(19) United States
(12) Patent Application Publication
(10) Pub. No.: US 2005/0025206 A1
(43) Pub. Date: Feb. 3, 2005

(54) Single-transverse-mode VCSEL device with array structure and fabrication method thereof

(76) Inventor: Chih-Cheng Chen, Taichung City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/899,851

(22) Filed: Jul. 27, 2004

(30) Foreign Application Priority Data
Jul. 29, 2003 (TW) 92120611

(51) Int. Cl. H01S 5/00

(52) U.S. Cl. 372/46; 372/45

(57) ABSTRACT

A single-transverse-mode VCSEL device with array structure and the fabrication method thereof. The single-transverse-mode VCSEL device with array structure comprises a plurality of light-emitting windows in a 1-D or 2-D array arrangement, and thereby provides high output power, low resistance, and a broad operating current range.

### BACKGROUND OF THE INVENTION

1. Field of the invention

The present invention relates to a vertical-cavity surface-emitting laser (VCSEL) device and the fabrication method thereof, and more particularly to a single-transverse-mode VCSEL device with array structure and the fabrication method thereof.

2. Description of the Related Art

A conventional vertical-cavity surface-emitting laser (VCSEL), as shown in FIG. 1, includes a semiconductor substrate 5, upper and lower distributed Bragg reflectors (DBR) 10 and 20 disposed on the substrate 5 with an active region 30 for laser emission inserted between the two DBRs. With its low threshold current, symmetric light beam, low far-field angle and other advantages, VCSEL has become a promising light source. Particularly, a VCSEL of single-transverse mode is suitable for short-distance optical communication systems, optical interconnection, optical storage, and laser printing. With the exception of optical communication systems, however, applications in other fields require relatively high output power. Thus a single-transverse-mode VCSEL device with an output power of 5-20 mW and low resistance broadens its applications to telecommunication (λ=1310 nm) and DVD (650 nm) fields.

Water oxidation is commonly used to fabricate a single-transverse-mode VCSEL device. However, water oxidation results in severe blockage of the transverse optical field, and the area of the active region must be reduced to form a stable single fundamental mode. For example, a single-transverse-mode VCSEL device of 850 nm should have an oxidation aperture smaller than 3 μm. In addition to difficulty in fabricating an active region in such a small area, huge device resistance (up to several hundreds ohms) results, heating the device, lowering the light-emitting efficiency, and even shortening product life.

To develop a single-transverse-mode VCSEL device with higher output power, diffraction-loss regions are formed outside the resonance cavity resulting in diffraction loss of high-order mode, thereby stabilizing the single-transverse-mode VCSEL device. Although the process provides a greater active region area of 6 μm, two steps of epitaxy are required and thus complicate the process. The University of Illinois reported a fabrication process involving both ion implantation and water oxidation. The output power of the single-transverse-mode VCSEL device was increased to about 5 mW, but the resistance was still high and it was hard to control the process since the ion-implantation area was only 6 μm and the active-region (current-flowing region) diameter formed by water oxidation was only 8 μm. The University of Arizona developed a single-high-order-mode VCSEL with an output power of 8 μm and a low resistance, but the far-field angles of the emitted light was so huge that it was not suitable for a DVD laser head.

To solve the problem, the applicant provided a fabrication method to form a light-emitting window, destroying the laser structure and thereby suppressing the high-order transverse mode, by diffusing zinc into the top stacking layers of DBRs, resulting in impurity-induced disorder. However, the diameter of the current-flowing region was only 10 μm under an optimum operation, causing a high resistance (about 120 ohm) and low output power of 2 mW.

SUMMARY OF THE INVENTION

Accordingly, an object of the present invention is to provide a single-transverse-mode vCSEL device with array structure having low resistance, high output power and applicable in various wavelengths (including 650 nm, 780 nm, 850 nm, 980 nm, 1310 nm, and 1550 nm).

Accordingly, another object of the present invention is to provide a fabrication method for a single-transverse-mode VCSEL device with array structure.

Therefore, one embodiment of the invention provides a single-transverse-mode VCSEL device with array structure which comprises a semiconductor substrate having a first surface and a second surface opposite to the first surface, a first-type distributed Bragg reflector on the first surface of the semiconductor substrate, a first-type electrode on the second surface of the semiconductor substrate, a first-type cladding layer on the first-type distributed Bragg reflector, an active layer having at least a current-flowing region and a plurality of current-blocking regions on the first-type cladding layer, a second-type cladding layer on the active layer, a second-type distributed Bragg reflector having a plurality of doped regions on the second-type cladding layer, wherein the doped regions reach a certain depth of the second-type distributed Bragg reflector from the upper surface of the second-type distributed Bragg reflector, and the second-type distributed Bragg reflector excluding the doped regions is defined as a plurality of light-emitting windows, and a second-type electrode on the doped regions.

According to the single-transverse-mode VCSEL device with array structure, the number of current-flowing regions may be less than that of the light-emitting windows. The light-emitting windows may have respective areas, meaning the light-emitting window areas can be the same or different. The light-emitting windows may respectively have a corresponding current-flowing-region area, meaning the corresponding current-flowing-region areas of the light-emitting windows can be the same or different. The area of the light-emitting window is not greater than that of its corresponding current-flowing region.

In the other hand, the active layer may have a plurality of current-flowing regions of respective areas, which means the areas of the current-flowing regions can be the same or different.

According to the single-transverse-mode VCSEL device with array structure, the current-flowing region may correspond to a common light emitting window or the plurality of light-emitting windows.

The present invention further provides a fabrication method embodiment of a single-transverse-mode VCSEL device with array structure, which comprises providing a semiconductor substrate with a first surface and a second surface opposite to the first surface, forming a first-type distributed Bragg reflector on the first surface of the semiconductor substrate, sequentially forming a first-type cladding layer, an active layer and a second-type cladding layer on the first-type distributed Bragg reflector, forming a second-type distributed Bragg reflector on the second-type cladding layer, forming a plurality of light-emitting windows and a plurality of doped regions in the second-type distributed Bragg reflector, wherein the light-emitting windows are separated by the doped regions, forming a first-type electrode on the second surface of the semiconductor substrate, and forming a second-type electrode on the doped regions.

According to one embodiment of the invention, the plurality of light-emitting windows of an array arrangement are provided with the single-transverse-mode VCSEL device to more effectively suppress the high-order transverse mode, reducing the resistance, increasing the output power and broadening the operating-current range. In addition to a 1-D array, the light-emitting windows can be extended to form a 2-D array and correspond to single or respective current-flowing regions to enhance their efficiency and applications.

### DESCRIPTION OF THE DRAWINGS

The present invention can be more fully understood by reading the subsequent detailed description and examples with references made to the accompanying drawings, wherein:

FIG. 1 is a cross-section of a conventional VCSEL;

FIGS. 2a-2h illustrates the fabrication process of the inventive single-transverse-mode VCSEL device with array structure;

FIG. 3 is a cross-section of a single-transverse-mode VCSEL device with a 2×1 array structure in an embodiment;

FIG. 4 is a cross-section of a single-transverse-mode VCSEL device with a 2×1 array structure in another embodiment;

FIG. 5 illustrates a cross-section of a single-transverse-mode VCSEL device with a 2×2 array structure according to the invention;

FIG. 6 shows the optical-electric characteristics of the single-transverse-mode VCSEL device with a 2×2 array structure according to the invention; and

FIG. 7 is a top-view showing a single-transverse-mode VCSEL device with a 2-D array structure according to the invention.

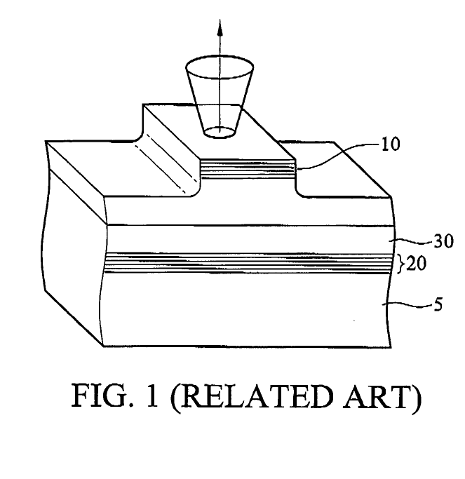

### DETAILED DESCRIPTION OF THE INVENTION

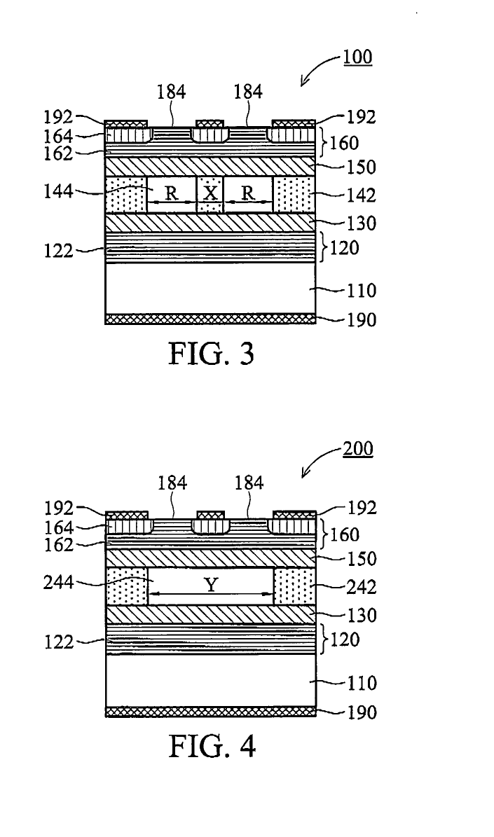

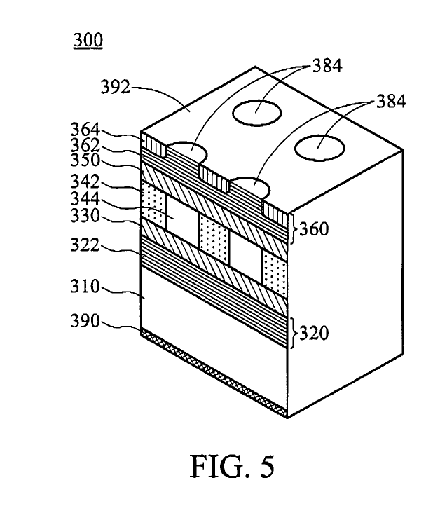

According to one embodiment of the invention, the provided single-transverse-mode VCSEL device with array structure comprises a first-type electrode, a semiconductor substrate with a first-type distributed Bragg reflector (DBR), a first-type cladding layer, an active layer, a second-type cladding layer, a second-type distributed Bragg reflector, at least two light-emitting windows and a second-type electrode. A portion of the second-type DBR forms a doped region while the active layer has at least a current-flowing region and a plurality of current-blocking regions. At least two light-emitting windows may correspond to respective current-flowing regions (as shown in FIG. 3) or a common current-flowing region (as shown in FIG. 4). At least two light-emitting windows can be formed in an 2-D array arrangement (as shown in FIG. 5 and FIG. 7) to further their efficiency and applications.

### FIRST EMBODIMENT

The first embodiment is given to explain the basic grain structure of the single-transverse-mode VCSEL device and the fabrication method thereof.

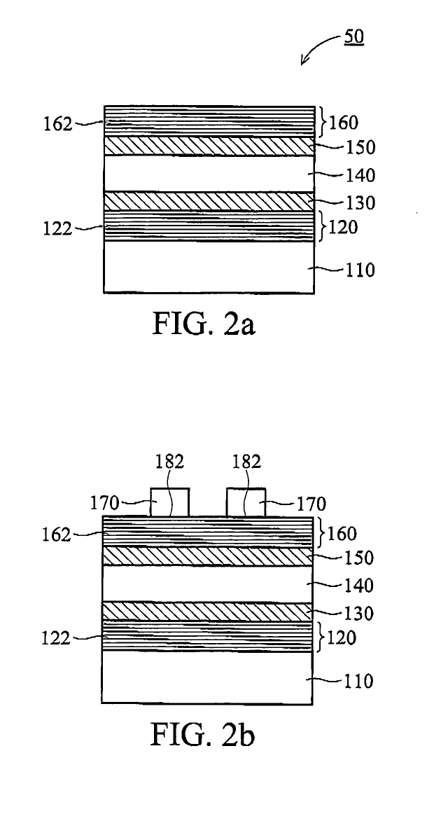

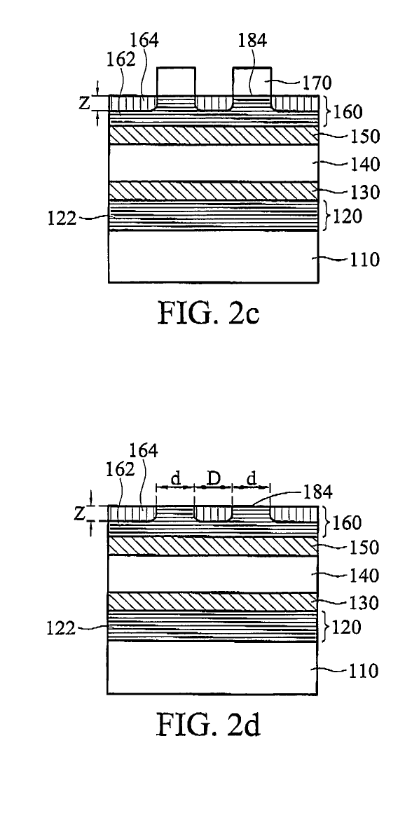

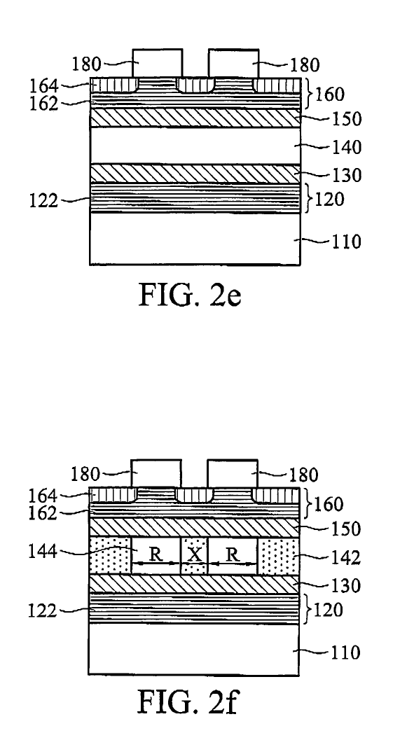

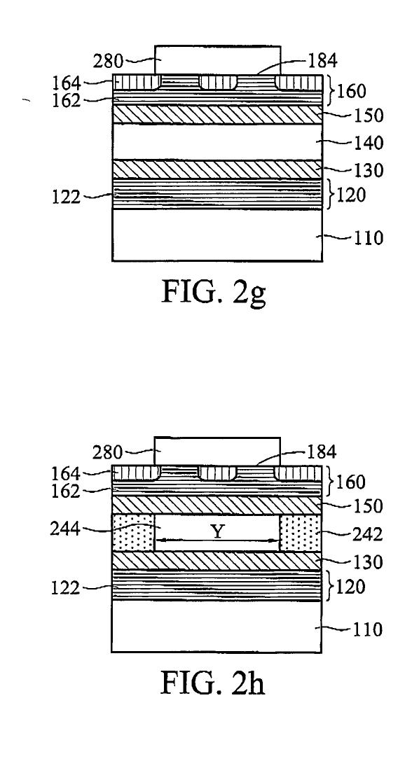

FIG. 2a shows the cross-section of the basic grain structure of the single-transverse-mode VCSEL device.

The grain 50 includes a semiconductor substrate 110, a first-type DBR 120, a first-type cladding layer 130, an active layer 140, a second-type cladding layer 150 and a second-type OBR 160. The fabrication method is described as follows.

First, a semiconductor substrate 110 is provided. A first-type DBR 120 is then formed on the semiconductor substrate 110. The semiconductor substrate 110 can be made of As, Al, Ga, In, Sb, Se, Ti, or Si, or a nitride, oxide, fluoride or a compound comprising at least one of the above elements. In this case, the semiconductor substrate 110 is an GaAs substrate. The first-type DSR 120 is mainly a stack of alternating layers of two different first-type layers 122, wherein the number of the layers is controlled to provide a preferable reflectivity of the first-type DBR 120. The first-type layers 122 can be made of arsenide, aluminide, galliumide, indiumide, antimonide, selenide or titanic compound of n-type, p-type or normal type. In this case, the alternating layers are n-type AlGaAs/AlGaAs layers, and the thickness of each layer is λ/4, wherein λ is the wavelength of the emitted light. The first-type DBR 120 can be made by liquid-phase epitaxy (LPE), vapor-phase epitaxy (VPE), molecular beam epitaxy (MBE), Metalorganic Chemical Vapor Deposition, electron beam evaporation or sputtering.

Next, a first-type cladding layer, an active layer and a second-type cladding layer are formed sequentially on the first-type DBR 120. The active layer is of a multiquantum-well structure, and forms a diode together with the first-type and second-type cladding layers. The structure of the diode is not limited; any kind of diode structure is applicable.

The active layer can be a multiquantum-well structure formed by alternatively stacking normal-type AlGaAs/AlGaAs layers. The cladding layers and the active layer may be formed by LPE, VPE, MOCVD or MBE. The VCSEL can be a laser diode of 650 nm, 780 nm, 850 nm, 980 nm, 1310 nm, or 1550 nm.

Finally, a second-type DBR 160 is formed on the second-type cladding layer 150. The second-type DBR 160 is mainly a stack of alternating layers of two different second-type layers 162, wherein the number of the layers is adjusted to give a preferable reflectivity of the second-type DBR 160. The second-type layers 162 can be made of arsenide, aluminide, galliumide, indiumide, antimonide, selenide or titanic compound of n-type, p-type or normal type. In this case, the alternating layers are p-type AlGaAs/AlGaAs layers, and the thickness of each layer is λ/4, wherein λ is the wavelength of the emitted light.

### SECOND EMBODIMENT

The second embodiment is taken to explain the fabrication method of the inventive single-transverse-mode VCSEL device with array structure.

FIGS. 2a-2f illustrate the fabrication process of the inventive single-transverse-mode VCSEL device with array structure, and FIG. 3 is a cross-section of a single-transverse-mode VCSEL device with a 2×1 array structure in the embodiment.

In FIG. 2a, a grain 50 with a basic structure as described in the first embodiment is provided.

In FIG. 2b, a patterned first mask layer 170 is formed on the second-type DBR 160 of the grain 50, covering predetermined areas designed to form two light-emitting windows 182. The predetermined areas of each light-emitting window are substantially the same, but adjustable based on requirements. The portion of the second-type DBR 160 not covered by the patterned first mask layer 170 is subject to a doping process. The first-mask layer 170 can be a dielectric material selected from the group consisting of oxides, nitrides, suicides, fluorides, and combinations thereof, for example, silicon nitride or silicon oxide. The thickness of the first-mask layer 170 is, for example, 500-2000 Å. The first-mask layer 170 is patterned by, for example, photolithography.

Next, as shown in FIG. 2c, the second-type DBR 160 is doped using the first-mask layer 170 as a mask to selectively dope a dopant into the regions not covered by the first mask layer 170 and thereby forming the doped regions 164. The doped regions 164 can be doped with Zn, Mg, Be, Sr, Ba, Si, Ge, Se, S, or Te by diffusion, ion implantation or regrowth. In this case, the doped regions 164 are doped with zinc by heat diffusion, wherein the grain and Zn₂As₃ particles are put into a quartz tube and heated to 650° C. under vacuum to perform the heat-diffusion process and thereby forming doped regions 164 on the second-type DBR 160. The doped regions 164 have a diffusion depth of Z, not smaller than 1 μm, for example, 1.5, or 2 μm, and not so thick as to cause absorption loss.

Then, as shown in FIG. 2d, the first mask layer 170 is removed to expose the un-doped regions of the second type DBR 160. The un-doped regions are served as the light-emitting windows 184. The light-emitting windows 184, having a width d of 3-7 μm, such as 6 μm, are separated from each other by the doped regions 164. The width d of each light-emitting window 184 can be the same or different. The distance D between two light-emitting windows 184 can be 1-8 μm, such as 6 μm.

Then, as shown in FIG. 2e, a second mask layer is formed on the substrate, and patterned by photolithography to form second-mask-layer patterns 180. The second-mask-layer patterns 180 covering each of the light-emitting windows 184 have a width R not smaller than the width d of the light-emitting windows 184. The width R of each second-mask-layer pattern can be the same or different. The second mask layer can be a thick photoresist layer formed by spin-coating or photolithography, or a thick metal layer with a thickness of 1.5 μm formed by electroplating.

Then, as shown in FIG. 2f, current-blocking regions are formed on the active layer 140 using the second-mask-layer patterns 180 to block the injected current path. The other portions of the active layer 140 serve as a current-flowing region 144 of the device. The current-flowing regions 144 are separated from each other by the current-blocking regions 142. The width R of the current-flowing region 144 is 5-12 μm, for example, 10 μm, and the width R of each current-flowing region 144 can be the same or different. The distance X between the current-flowing regions 144 can be 1-8 μm, for example, 5 μm. The current-blocking regions 142 can be formed by ion implantation, diffusion, water oxidation, or mesa etching. In this case, the current-blocking regions 142 are formed by implantation, for example, 1×10¹⁴/cm²-8×10¹⁴/cm² of hydrogen- or oxygen-ions with a power of 300 KeV.

Finally, as shown in FIG. 3, the second-mask-layer patterns 180 are removed. A first-type electrode 190 is formed on the lower surface of the semiconductor substrate 110 by evaporation, electroplating, sputtering or vapor phase deposition, while a second-type electrode 192 is formed on the doped regions 164 to complete electric contact. The materials of the electrodes are not limited; any conductive material is applicable based on requirements.

Accordingly, the single-transverse-mode VCSEL with a 2×1 array structure is provided, wherein each of the light-emitting windows corresponds to a respective current-flowing region.

### THIRD EMBODIMENT

According to the invention, the light-emitting windows can correspond to respective current-flowing regions as shown in the second embodiment, or correspond to a common current-flowing region as described herein.

FIG. 2g, FIG. 2h and FIG. 4 show the fabrication process of another single-transverse-mode VCSEL with a 2×1 array structure.

First, the doped regions and the current-flowing regions are formed according to the steps described in the second embodiment.

Then, as shown in FIG. 2h, current-blocking regions 242 are formed on the active layer 140 using the second-mask-layer patterns 280 to block the injecting current path. The other part of the active layer 140 serves as a current-flowing region 244 of the device. The current-flowing region 244 is not separated by the current-blocking regions 242. The width Y of the current-flowing region 244 is 7-26 μm, for example, 20 μm, and Y is not smaller than 2d+D. The current-blocking regions 242 can be formed by the methods as described in the second embodiment.

Finally, as shown in FIG. 4, the patterned second mask layer 280 is removed. A first-type electrode 190 is formed on the lower surface of the semiconductor substrate 110 while a second-type electrode 192 is formed on the doped regions 164 to complete electric contact.

Accordingly, the single-transverse-mode VCSEL with a 2×1 array structure is provided, wherein the light-emitting windows correspond to a common current-flowing region.

### FOURTH EMBODIMENT

According to the invention, the light-emitting windows can be extended to form a 2-D array to further their efficiency and applications.

As shown in FIG. 5, a fabrication process similar to that of the second embodiment is applied, except that four light-emitting windows (of a 2×2 array arrangement), instead of two light-emitting windows (of a 2×1 array arrangement), are formed. The numbers of their corresponding regions, such as the doped regions and current-blocking regions, are altered to four, accordingly. The current-flowing regions can be designed as four regions respectively corresponding to the four light-emitting windows, two regions respectively corresponding to two of the light-emitting windows, or one region corresponding to four of the light-emitting windows.

In the embodiment, four current-flowing regions 344 are provided respectively and correspond to the four light-emitting windows 384. The single-transverse-mode VCSEL has a threshold current of 3-6 mA, a resistance of 25-52 ohm and a max. output power of >7 mW. Also, a characteristic of single-transverse mode (mode suppression ratio >30 dB) is shown in the measured spectrum. Accordingly, the output power can be raised by increasing the number of light-emitting windows to, for example, 3×3, or 3×4.

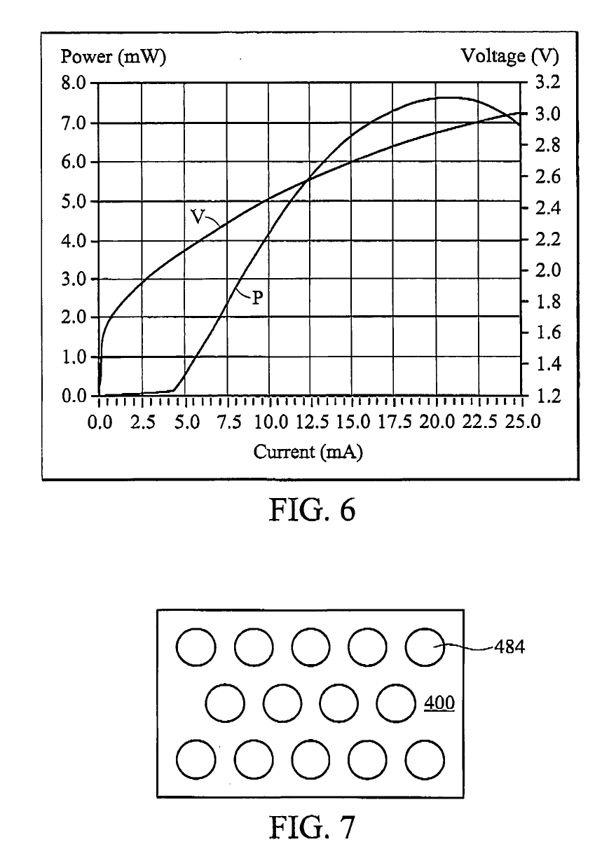

FIG. 6 shows the optical-electric characteristics of the single-transverse-mode VCSEL device with a 2×2 array structure according to the fourth embodiment. It is shown that a high output power (max. 7.5 mW), low resistance (about 51 ohm) and a broad operating current range (about 0-25 mA) are achieved by increasing the number of the light-emitting windows according to the invention. Meanwhile, the light-emitting windows may be extended to a 2-D array arrangement (as shown in FIG. 7) and respectively correspond to separate current-flowing regions (as the second embodiment) or together correspond to a common current-flowing region (as the third embodiment).

Accordingly, compared with the conventional device with a single light-emitting window, the inventive single-transverse-mode VCSEL device avoids the disadvantages resulting from the small current-flowing region (the diameter of the conventional current-flowing region is only allowed to be under 10 μm), reducing the resistance (conventional: 120 ohm; present: 51 ohm), and raising the output power (conventional: 2 mW; present: 7.5 mW). Therefore, the invention avoids the disadvantages resulting from the single-fundamental mode or the single-high-order mode, and is suitable for a surface-emitting laser of various wavelengths (including 650 nm, 780 nm, 850 nm, 980 nm, 1310 nm, or 1550 nm).

The foregoing description has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

1. A single-transverse-mode VCSEL device with array structure, comprising:
a semiconductor substrate having a first surface and a second surface opposite to the first surface;
a first-type distributed Bragg reflector on the first surface of the semiconductor substrate;
a first-type electrode on the second surface of the semiconductor substrate;
a first-type cladding layer on the first-type distributed Bragg reflector;
an active layer having at least a current-flowing region and a plurality of current-blocking regions on the first-type cladding layer;
a second-type cladding layer on the active layer;
a second-type distributed Bragg reflector having a plurality of doped regions on the second-type cladding layer, wherein the doped regions reach a certain depth of the second-type distributed Bragg reflector from the upper surface of the second-type distributed Bragg reflector, and the second-type distributed Bragg reflector excluding the doped regions is defined as a plurality of light-emitting windows; and
a second-type electrode on the doped regions.

2. The single-transverse-mode VCSEL device with array structure as claimed in claim 1, wherein the active layer has a multiquantum-well structure.

3. The single-transverse-mode VCSEI device with array structure as claimed in claim 1, wherein the current-blocking regions are formed by ion implantation, diffusion, water oxidation, or mesa etching.

4. The single-transverse-mode VCSEL device with array structure as claimed in claim 1, wherein the current-blocking regions are formed by hydrogen- or oxygen-ion implantation.

5. The single-transverse-mode VCSEL device with array structure as claimed in claim 1, wherein the current-blocking regions are implanted by 1×10¹⁴/cm²-8×10¹⁴/cm² of ions.

6. The single-transverse-mode VCSEL device with array structure as claimed in claim 1, wherein the active layer has a plurality of current-flowing regions separated from each other by the current-blocking regions.

7. The single-transverse-mode VCSEL device with array structure as claimed in claim 1, wherein the light-emitting windows are separated from each other by the doped regions.

8. The single-transverse-mode VCSEL device with array structure as claimed in claim 1, wherein the number of the current-flowing regions is less than that of the light-emitting windows.

9. The single-transverse-mode VCSEL device with array structure as claimed in claim 1, wherein the light-emitting windows have respective areas.

10. The single-transverse-mode VCSEL device with array structure as claimed in claim 1, wherein the light-emitting windows respectively have a corresponding current-flowing-region area.

11. The single-transverse-mode VCSEL device with array structure as claimed in claim 1, wherein the active layer has a plurality of current-flowing regions of respective areas.

12. The single-transverse-mode VCSEL device with array structure as claimed in claim 1, wherein the current-flowing region corresponds to the plurality of light-emitting windows.

13. The single-transverse-mode VCSEL device with array structure as claimed in claim 1, wherein the current-flowing region corresponds to a common light emitting window.

14. The single-transverse-mode VCSEL device with array structure as claimed in claim 1, wherein the area of the light-emitting window is not greater than that of its corresponding current-flowing region.

15. The single-transverse-mode VCSEL device with array structure as claimed in claim 1, wherein the doped regions are doped with Zn, Mg, Be, Sr, Ba, Si, Ge, Se, S, or Te.

16. The single-transverse-mode VCSEL device with array structure as claimed in claim 1, wherein the light-emitting windows form a 1-D or 2-D array.

17. A fabrication method of a single-transverse-mode VCSEL device with array structure, comprising:
providing a semiconductor substrate with a first surface and a second surface opposite to the first surface;
forming a first-type distributed Bragg reflector on the first surface of the semiconductor substrate;
sequentially forming a first-type cladding layer, an active layer, and a second-type cladding layer on the first-type distributed Bragg reflector;
forming a second-type distributed Bragg reflector on the second-type cladding layer;
forming a plurality of light-emitting windows and a plurality of doped regions in the second-type distributed Bragg reflector, wherein the light-emitting windows are separated by the doped regions;
forming a first-type electrode on the second surface of the semiconductor substrate; and
forming a second-type electrode on the doped regions.

18. The fabrication method as claimed in claim 17, wherein the process of forming the light-emitting windows and the doped regions comprises:
forming a patterned first mask layer on the second-type distributed Bragg reflector, wherein the regions of the second-type distributed Bragg reflector, covered by the patterned first mask, are defined as light-emitting windows;
doping the second-type distributed Bragg reflector with the patterned first mask layer as a doping mask to form the doped regions, wherein said doped regions reach a certain depth of the second-type distributed Bragg reflector from the upper surface of the second-type distributed Bragg reflector; and
removing the patterned first mask layer to expose the light-emitting windows.

19. The fabrication method as claimed in claim 18, further comprising:
forming a patterned second mask layer on the light-emitting windows and a part of the second-type distributed Bragg reflector, wherein an active-layer region corresponding to the patterned second mask layer is a predetermined light-emitting region;
performing a current-blocking process on the active layer with the patterned second mask layer as a mask to form a plurality of current-blocking regions, thereby defining the active-layer region not performed with a current-blocking process as a current-flowing region; and
removing the patterned second mask layer.

20. The fabrication method as claimed in claim 17, wherein the light-emitting windows form a 1-D or 2-D array.

21. The fabrication method as claimed in claim 17, wherein the light-emitting windows have respective areas.

22. The fabrication method as claimed in claim 18, wherein the second-type distributed Bragg reflector is doped by diffusion, ion implantation or regrowth.

23. The fabrication method as claimed in claim 18, wherein the doped regions are doped with Zn, Mg, Be, Sr, Ba, Si, Ge, Se, S, or Te.

24. The fabrication method as claimed in claim 19, wherein the current-blocking regions are formed by ion implantation, diffusion, water oxidation or mesa etching.

25. The fabrication method as claimed in claim 19, wherein the current-blocking regions are formed by hydrogen- or oxygen-ion implantation.

26. The fabrication method as claimed in claim 25, wherein the current-blocking regions are implanted by 1×10¹⁴/cm²-8×10¹⁴/cm² of ions.

27. The fabrication method as claimed in claim 19, wherein a plurality of current-flowing regions, separated from each other by the current-blocking regions, are formed on the active layer after performing the current-blocking process.

28. The fabrication method as claimed in claim 19, wherein a single current-flowing region is formed on the active layer after performing the current-blocking process.

29. The fabrication method as claimed in claim 19, wherein the number of the current-flowing regions is less than that of the light-emitting windows.

30. The fabrication method as claimed in claim 19, wherein the light-emitting windows respectively have a corresponding current-flowing-region area.

31. The fabrication method as claimed in claim 19, wherein a plurality of current-flowing regions of respective areas are formed on the active layer.

32. The fabrication method as claimed in claim 19, wherein the current-flowing region corresponds to the plurality of light-emitting windows.

33. The fabrication method as claimed in claim 19, wherein the current-flowing region corresponds to a common light emitting window.

34. The fabrication method as claimed in claim 19, wherein the area of the light-emitting window is not greater than that of its corresponding current-flowing region.
